(19) United States
(12) Patent Application Publication
(10) Pub. No.: US 2024/0040783 A1
(43) Pub. Date: Feb. 1, 2024

(54) FLASH MEMORY WITH IREAD TUNING

(71) Applicant: TEXAS INSTRUMENTS INCORPORATED, Dallas, TX (US)

(72) Inventors: Toan Tran, Murphy, TX (US); Stephen A. Keller, Plano, TX (US)

(21) Appl. No.: 17/877,807

(22) Filed: Jul. 29, 2022

(51) Int. Cl. H01L 27/11521; H01L 29/423; H01L 29/788; H01L 21/28; H01L 29/66

(52) U.S. Cl. CPC H01L 27/11521; H01L 29/42328; H01L 29/7881; H01L 29/40114; H01L 29/66825

(57) ABSTRACT

A Flash IC device having I_{READ} compensation and a method of fabricating the same. Responsive to determining a gate pattern misalignment, one or more implant conditions for implanting a dopant may be selected to achieve balanced I_{READ} characteristics between adjacent bitcells of the Flash IC device.

### FIELD OF THE DISCLOSURE

Disclosed implementations relate generally to the field of semiconductor memory and fabrication. More particularly, but not exclusively, the disclosed implementations relate to Flash memory having read current (I_{READ}) tuning.

### BACKGROUND

A non-volatile-memory bitcell is an electronic element that is configured to store information. A threshold voltage can be used to discriminate between logic levels of the bitcell, such as a logic low level (“0”) or a logic high level (“1”). This stored value may sometimes be referred to as information (or a bit), which may be read by sense amplifier circuitry.

### SUMMARY

The following presents a simplified summary in order to provide a basic understanding of some examples of the present disclosure. This summary is not an extensive overview of the examples, and is neither intended to identify key or critical elements of the examples, nor to delineate the scope thereof. Rather, the primary purpose of the summary is to present some concepts of the present disclosure in a simplified form as a prelude to a more detailed description that is presented in subsequent sections further below.

Examples of the present disclosure are directed to methods and devices that compensate for misalignment between a wordline (WL) and a control gate (CG) of an adjacent pair of memory bitcells to reduce a difference of I_{READ} of the pair of memory bitcells of a Flash memory device. In one arrangement, responsive to determining a gate pattern misalignment, a dopant may be implanted under conditions selected to target result in balanced I_{READ} characteristics between the adjacent bitcells of the Flash memory device.

In one example, a method of fabricating an integrated circuit (IC) is disclosed. The method may comprise, inter alia, forming a first control gate of a first memory bitcell and a second control gate of a second memory bitcell over a semiconductor substrate. A common source region of the first and second memory bitcells in the semiconductor substrate may be formed between the first and second control gates. Thereafter, a gate electrode layer may be formed over the first and second control gates. In one arrangement, the gate electrode layer may be patterned, thereby forming a first wordline adjacent the first control gate and a second wordline adjacent the second control gate, the first wordline having a first width and the second wordline having a second width. In one arrangement, a first drain region extending under the first wordline may be formed using first implant parameters and a second drain region extending under the second wordline may be formed using different second implant parameters.

In another example, an IC including a Flash memory is disclosed. The IC may comprise, inter alia, a first memory bitcell over a semiconductor substrate and including a first gate stack including a first floating gate and a first control gate with a dielectric material disposed therebetween, the first memory bitcell further including a first wordline formed adjacent to a drain region of the first memory bitcell, the drain region of the first memory bitcell coupled to a first bitline; a second memory bitcell spaced apart over the semiconductor substrate from the first memory bitcell by a common source region shared between the first and second memory bitcells, the second memory bitcell including a second gate stack including a second floating gate and a second control gate with a dielectric material disposed therebetween, the second memory bitcell further including a second wordline formed adjacent to a drain region of the second memory bitcell, the drain region of the second memory bitcell coupled to a second bitline; and an erase gate formed over the common source region, wherein the drain region of the first memory bitcell has a different dopant profile than does the drain region of the second memory bitcell.

In another example, a Flash memory bitcell is disclosed, which comprises, inter alia, a gate stack formed over a semiconductor substrate, the gate stack including a floating gate and a control gate with a dielectric material disposed therebetween; a common source region formed in the semiconductor substrate adjacent to the gate stack; a first wordline formed adjacent the gate stack; an erase gate overlapping at least a portion of the common source region; and a first drain region formed in the semiconductor substrate and extending under the first wordline, and a second drain region formed in the semiconductor substrate and extending under a second wordline, wherein the first wordline has a first width that is different from a second width of the second wordline of an adjacent Flash memory bitcell sharing the common source with the Flash memory cell. In one arrangement, the first drain region of the Flash memory bitcell has a different physical characteristic with respect to the second drain region of the adjacent Flash memory bitcell. In some implementations, the first drain region of the first memory bitcell has a first dopant dosage and the second drain region of the second memory bitcell has a different second dopant dosage. In some implementations, the first drain region of the first memory bitcell extends further under the first wordline than the second drain region of the second memory bitcell extends under the second wordline. In some implementations, the first drain region of the first memory bitcell extends deeper into the semiconductor substrate that does the second drain region of the second memory bitcell.

### BRIEF DESCRIPTION OF THE DRAWINGS

Implementations of the present disclosure are illustrated by way of example, and not by way of limitation, in the Figures of the accompanying drawings. It should be noted that different references to “an” or “one” implementation in this disclosure are not necessarily to the same implementation, and such references may mean at least one. Further, when a particular feature, structure, or characteristic is described in connection with an implementation, it is submitted that it is within the knowledge of one skilled in the art to effect such feature, structure, or characteristic in connection with other implementations whether or not explicitly described.

The accompanying drawings are incorporated into and form a part of the specification to illustrate one or more example implementations of the present disclosure. Various advantages and features of the disclosure will be understood from the following Detailed Description taken in connection with the appended claims and with reference to the attached drawing Figures in which:

FIG. 1A depicts a cross-sectional view of a pair of Flash memory bitcells wherein read current (I_{READ}) may be determined according to some examples of the present disclosure;

FIG. 1B depicts a schematic layout pattern corresponding to the bitcells of FIG. 1A illustrating gate overlay alignment that may be susceptible to process variations;

FIG. 2 depicts an integrated circuit (IC) having a memory array comprising a plurality of bitcells exemplified by the bitcells of FIG. 1A according to some examples of the present disclosure;

FIGS. 3A-3C depict schematic plan views of aligned or misaligned patterns of wordline overlay of common source corresponding to the bitcells of FIG. 1A wherein I_{READ} may be balanced based on compensation according to some examples of the present disclosure;

FIGS. 4A-4J depict a plurality of process stages for fabricating a pair of adjacent bitcells according to some examples of the present disclosure;

FIG. 5 is a flowchart of a fabrication method according to some examples of the present disclosure;

FIG. 6 is a flowchart associated with an I_{READ} characterization and compensation scheme according to some examples of the present disclosure;

FIG. 7A depicts a system for facilitating I_{READ} compensation in association with gate pattern overlay control during the fabrication of an IC according to some examples of the present disclosure;

FIG. 7B depicts an implanter subsystem operable in association with gate pattern overlay control provided as part of the system of FIG. 7A for tuning the bitcell read characteristics according to some examples of the present disclosure; and

FIG. 8 is a flowchart of a method according to some examples of the present disclosure.

### DETAILED DESCRIPTION

Examples of the disclosure are described with reference to the attached Figures wherein like reference numerals are generally utilized to refer to like elements. The Figures are not drawn to scale and they are provided merely to illustrate examples. Numerous specific details, relationships, and methods are set forth below to provide an understanding of one or more examples. However, it should be understood that some examples may be practiced without such specific details. In other instances, well-known subsystems, components, structures and techniques have not been shown in detail in order not to obscure the understanding of the examples. Accordingly, it will be appreciated by one skilled in the art that the examples of the present disclosure may be practiced without such specific components.

Additionally, terms such as “coupled” and “connected,” along with their derivatives, may be used in the following description, claims, or both. It should be understood that these terms are not necessarily intended as synonyms for each other. “Coupled” may be used to indicate that two or more elements, which may or may not be in direct physical or electrical contact with each other, co-operate or interact with each other. “Connected” may be used to indicate the establishment of communication, i.e., a communicative relationship, between two or more elements that are coupled with each other. “Directly connected” may be used to convey that two or more physical features touch, or share an interface between each other. Further, in one or more examples set forth herein, generally speaking, an element, component or module may be configured to perform a function if the element may be programmed for performing or otherwise structurally arranged to perform that function.

Without limitation, examples of the disclosure will be set forth below in the context of Flash memory read current (I_{READ}) characterization and compensation.

Various disclosed methods and devices of the present disclosure may be beneficially applied to integrated circuits that include a Flash memory array to determine dopant implant characteristics and/or parameters based on gate-WL alignment during the formation of gate structures in a fabrication flow. While such examples may be expected to provide improvements in performance, such as improved read reliability across the array, no particular result is a requirement of the present invention unless explicitly recited in a particular claim.

Flash memory is a nonvolatile storage medium that may store information in an array of memory cells, also referred to as bitcells. This stored information (or “bits”) can be electrically programmed by placing charge on a floating gate, read and erased. In some cases, an array of floating-gate transistor bitcells may be used in creating a Flash memory circuit or device. A floating-gate transistor bitcell resembles a standard metal-oxide-field-effect-transistor (MOSFET), with exceptions including the floating-gate transistor bitcell including multiple gates (e.g., a control gate overlying a conductively isolated floating gate). An electrical state of a bitcell can be used to define a logic level such as a logic low level (e.g., a digital low or “0”) or a logic high level (e.g., digital high or “1”) depending on the Boolean logic used by a sense circuit for reading the data in a read operation. This defined logic level may sometimes be referred to as information (or a bit) stored in the bitcell.

Storage of information may be effectuated using changes in the floating gate characteristics of the bitcells. The threshold voltage (V T) of a floating-gate type transistor bitcell may change because of the presence or absence of a charge trapped in its floating gate due to electrical isolation. The trapped charge alters the threshold voltage (relative to the unchanged threshold voltage) of the floating-gate transistor bitcell. For instance, in an example NMOS-based Flash implementation, the threshold voltage is increased when electrons are trapped in the floating gate of the bitcell (e.g., a “programmed” bitcell). On the other hand, the threshold voltage is decreased when electrons are depleted in the floating gate of an NMOS bitcell (e.g., an “erased” bitcell). Accordingly, when a voltage is applied to the control gate of a bitcell of an NMOS-based Flash memory array during the read operation, the bitcell is conductive in an erased state and nonconductive in a programmed state, wherein each state is operative for generating a corresponding read current (I_{READ}) that is provided to a sense amplifier for sensing the data. In an example arrangement, the sense amplifier may be configured to determine the data relative to another current, referred to as a reference current (I_{REF}). In PMOS-based Flash implementation, these relationships are opposite, in that the PMOS bitcells are conductive in programmed state and non-conducting in erased state. In general, regardless of whether PMOS-based or NMOS-based NVM is implemented, a read current generated when the bitcell is conducting may be referred to as “ON” read current (I_{ON}), indicating a logic level of a first type. Similarly, a read current generated when the bitcell is non-conducting may be referred to as “OFF” read current (I_{OFF}) that is indicative of a logic level of a second type complementary to the first type.

In some implementations, floating-gate transistor bitcells may utilize a split-gate architecture to store bits, wherein a split-gate Flash bitcell may include more than one transistor. For example, a split-gate Flash memory bitcell may have a gate portion (referred to as a wordline) adjacent to the control gate that is disposed over the floating gate, such that the channel of the memory bitcell is controlled by the wordline gate as well as the floating gate. This arrangement causes the split-gate Flash memory bitcell to act as two transistors operating in series, equivalent to 1.5 transistors (1.5T) per cell in some implementations such as those in which two Flash bitcells may share a source or a drain (depending on NMOS or PMOS implementation). Similarly, in some configurations, the split-gate Flash bitcell can have a 2T (two transistors) configuration. In general operation, a combination of one or more of the gates of a split-gate bitcell can be configured to program, erase, and/or read the bitcell.

Example split-gate Flash bitcell architecture may include a source line, a bitline (BL), a control gate (CG), a wordline (WL), a floating gate (FG), and an erase gate (EG), wherein a common source (CS) terminal may be shared between two adjacent bitcells that each have a drain coupled to respective bitline. Such bitcell architecture is sometimes referred to as 3^{rd} generation SuperFlash technology (ESF3) bitcell architecture, and bitcells using ESF3 bitcell architecture are referred to as ESF3 bitcells. Because the wordline and erase gate pattern is typically aligned to the control gate pattern during the fabrication, a gate overlay misalignment can cause asymmetrical channels in a pair of adjacent bitcells, wherein different read currents (I_{READ}) may be generated during a read operation depending on the amount of channel asymmetry between the two bitcells. It should be appreciated that such I_{READ} variances are undesirable inasmuch as false logic levels may be sensed by the sense circuitry, thereby leading to data read errors.

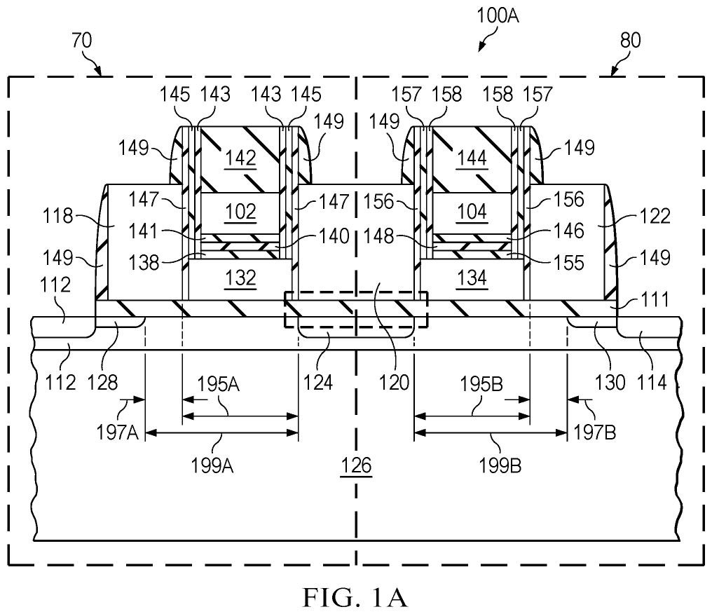

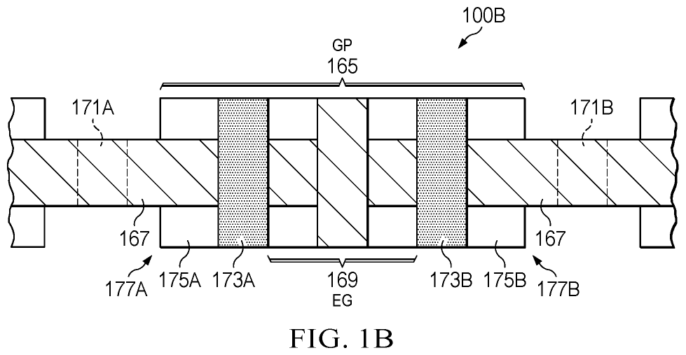

FIG. 1A depicts a cross-sectional view 100A of a pair of Flash memory bitcells wherein read current (I_{READ}) may be determined according to some examples of the present disclosure. By way of illustration, bitcell 70 and bitcell 80 are shown, each of which may be coupled to a respective bitline, wherein bitcells 70 and 80 are substantially similar in structure. Depending on how a memory array containing bitcells 70 and 80 is organized and oriented in an IC die formed on a semiconductor process wafer, bitcells 70 and 80 may be adjacent to each other in a vertical direction (e.g., laterally along a Y-axis in the plane of the semiconductor process wafer) or in a horizontal direction (e.g., laterally along an X-axis in the plane of the semiconductor process wafer). Accordingly, bitcells 70 and 80 shown in cross-sectional view 100A may be referred to as “top” or “bottom” bitcells, or “left” or “right” bitcells depending on orientation. Bitcell 70 may include a drain or bitline 112 that is disposed in a substrate 126 (also referred herein as a semiconductor substrate 126), e.g., a portion of semiconductor process wafer. Bitcell 70 may include a wordline (WL) 118, a control gate 102, a floating gate 132, and an erase gate 120 that is also shared by bitcell 80, wherein control gate 102 and floating gate 132 may be referred to as a gate stack. In some examples, wordline 118 may be referred to as a first gate, erase gate 120 may be referred to as a second gate, and control gate 102 may be referred to as a third gate. In some arrangements, one or more dielectric layers, e.g., dielectric layers 138, 140, 141, may be disposed between control gate 102 and floating gate 132 to provide vertical isolation therebetween. In some examples, bitcell 70 may also include one or more dielectric layers 143, 145, 147 that provide horizontal isolation between wordline 118 and control gate 102, and between control gate 102 and erase gate 120. In some arrangements, dielectric layer 147 may be extended to also provide horizontal isolation between wordline 118 and floating gate 132, and between floating gate 132 and erase gate 120. In some examples, dielectric layers 138, 141, 143, and 147 may include silicon dioxide, and dielectric layers 140, 145 may include silicon nitride.

A gate dielectric layer 111 overlying an active area of substrate 126 may be extended between bitcells 70, 80 for providing floating gate isolation. With respect to bitcell 70, the gate dielectric layer 111 provides isolation between floating gate 132 and an active area formed in substrate 126 that may include one or more doped regions to support and condition a channel depending on implementation as will be set forth further below. Bitcell 70 may also include a dielectric layer 142 that provides vertical isolation of control gate 102. Bitcell 70 includes a WL transistor that comprises wordline 118 (operable analogous to a gate of a MOSFET), bitline 112 (operable analogous to a drain of a MOSFET), and a common source line 124 (operable analogous to a source of a MOSFET) that is shared with adjacent bitcell 80. Because wordline 118 may operate as a gate with respect to bitcell 70, wordline 118 may sometimes be referred to equivalently as a wordline gate. In some variations, bitcell 70 may also include a doped extension region 128 of bitline 112 that is disposed in substrate 126. In general, doped extension region 128 may be considered to be analogous to a lightly-doped drain (LDD) extension of a MOSFET. In some examples, doped extension region 128 may be used to alter the threshold voltage of the WL transistor. In some examples, substrate 126 also includes an additional doped region, such as a doped region 136, e.g., an anti-punch-through layer that is formed by implanting suitable dopants (e.g., boron) in the substrate 126.

Similar to bitcell 70, bitcell 80 includes a drain or bitline 114, common source line 124, erase gate 120, a floating gate 134, a control gate 104, and a wordline 122, wherein a control gate 104 and floating gate 134 may be formed as a gate stack structure as will be set forth further below. A dielectric layer 144 may be provided for isolating the control gate 104 of the gate stack structure. Bitcell 80 may include one or more dielectric layers 146, 148, 155 for providing vertical isolation between control gate 104 and floating gate 134. In some examples, bitcell 80 may also include one or more dielectric layers 156, 157, 158 that provide horizontal isolation between wordline 122 and control gate 104, and control gate 104 and erase gate 120. Dielectric layer 157 may be extended to provide horizontal isolation between wordline 122 and floating gate 134, and floating gate 134 and erase gate 120. Similar to the dielectric layers of bitcell 70, dielectric layers 146, 155, 156, and 158 of bitcell 80 may include silicon dioxide, and dielectric layers 148, 157 of bitcell 80 may include silicon nitride in some example implementations.

As such, one or more of the various dielectric layers of bitcell 70 may be operative to isolate wordline 118, control gate 102, floating gate 132, and erase gate 120 from each other. Likewise, one or more of the various dielectric layers of bitcell 80 may be operative to isolate wordline 122, control gate 104, floating gate 134, and erase gate 120 from each other. As previously noted, gate dielectric layer 111 extends to bitcell 80 for providing isolation between floating gate 134 and an active area formed in substrate 126. Bitcell 80 may also include a doped extension region 130 that is disposed below wordline 122 in substrate 126. In some examples, bitcells 70, may each include sidewall spacers 149 disposed on the vertical edges of respective wordlines 118, 122 and respective dielectric layers 147, 156.

In some examples, wordlines 118, 122, and control gates 102, 104, and floating gates 132, 134 may each comprise polysilicon. In some examples, bitcells 70, 80 may be fabricated as part of an IC (e.g., in a semiconductor die that includes additional circuitry, including logic and/or analog circuitry. In other examples, bitcells 70, 80 may be fabricated as a standalone device, for instance, implemented in a semiconductor die that includes an array of bitcells, such as bitcells 70, 80 and circuitry associated therewith. For simplicity, FIG. 1A depicts a single pair of bitcells 70, 80 that may be disposed laterally next to each other along the X-axis or Y-axis in the plane of the process wafer depending on orientation as noted previously. Whereas some of the examples herein may specifically refer to bitcell 70, the description of bitcell 70 may also apply to bitcell 80, and more generally to an array of bitcells employing bitcells such as bitcells 70/80, mutatis mutandis.

Bitcells 70 and 80 may each have a channel length 199A, 199B that may be based on a plurality of gate patterning processes, wherein the dimensions may be defined during a mask design process responsive to appropriate design rules. Channel length 199A of bitcell 70 may comprise a WL-based portion 197A between the extension region 128 and the FG 132, and a CG/FG-based portion 195A between the FG 132 and the CS 124. Likewise, channel length 199B of bitcell 80 may comprise a WL-based portion 197B between the extension region 130 and the FG 134, and a CG/FG-based portion 195B between the FG 134 and the CS 124. Due to the gate alignment stages involved in patterning the various gates of bitcells 70 and 80, a misalignment between the patterns of WLs 118, 122 and the CG/FG stacks in either direction along an axis parallel to channel lengths 199A/199B may cause asymmetrical WL-based portions 197A and 197B (and correspondingly asymmetrical channel lengths 199A, 199B) to be formed for the adjacent bitcells 70, 80. Accordingly, adjacent bitcells 70, 80 may exhibit different read current characteristics because of the channel asymmetry, which can give rise data errors as noted previously.

FIG. 1B depicts an example schematic layout pattern 100B corresponding to a pair of memory bitcells illustrating gate overlay alignment at different gate layers in an example arrangement. By way of illustration, layout portion 177A and layout portion 177B respectively correspond to two adjacent bitcells, e.g., bitcell 70 and bitcell 80 of FIG. 1A described above. Layout portions 177A, 177B each comprise a WL portion 175A, 175B, respectively, which may be defined in a same gate pattern, e.g., a composite gate pattern 165, for defining a shared EG pattern 169 in some example arrangements. Gate pattern 165 including WL portions 175A, 175B and EG portion 169 is operable to define a gate layer that may be disposed above a control gate layer defined by a control gate pattern comprising respective control gate portions 173A, 173B with respect to the two adjacent bitcells. An active area pattern 167 includes the bitlines 112, 114, and is operable to define an active area in a semiconductor substrate for fabricating the adjacent bitcells as will be described further below. Contacts 171A, 171B may be defined in a contact layer pattern for providing drain contacts with respect to the underlying bitlines 112, 114. A misalignment between gate pattern 165 in a direction normal to the underlying control gate pattern 173A, 173B can cause the wordline portion 175A to have a different width than the wordline portion 175B, resulting in a wordline for one bitcell having a first width that is larger or smaller than a second width of the wordline for the adjacent bitcell. The width of a particular wordline is defined as the distance to which that wordline extends between a first side closer to the control gate immediately adjacent the wordline to an opposite second side of the wordline. Whereas appropriate gate overlay control rules may be implemented to identify gross misalignment between the gate layers (e.g., in order to determine whether process wafers containing the ICs with misaligned WL and CG layers need to be scrapped or sent to rework), there may be instances where the gate overlay alignment is within applicable process thresholds but may still be susceptible to process variations that can cause WL asymmetry. Concomitantly, I_{READ} differences may exist between the two adjacent bitcells even where the gate overlay is within the process thresholds in some example arrangements.

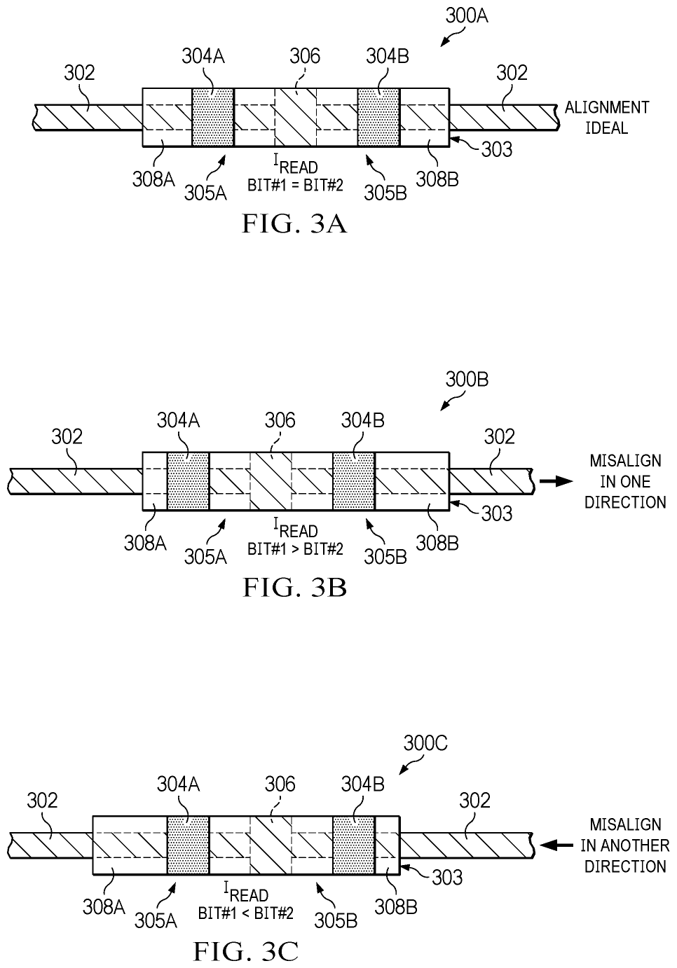

FIGS. 3A-3C depict schematic representations of alignment or misalignment patterns of gate overlay corresponding to the bitcells of FIG. 1A wherein asymmetrical I_{READ} may be caused according to some examples. Gate overlay pattern 300A shown in FIG. 3A is illustrative of a WL/EG pattern 303 comprising WL portions 308A, 308B (corresponding to two adjacent bitcells 305A, 305B) and an EG portion 306. As illustrated, pattern 303 is accurately aligned to underlying CG portions disposed over an active area 302 extended between bitcells 305A/305B. Being accurately aligned, the WL/EG pattern 303 is centered over the CG portions 304A, 304B and extends equally past the CG portion 304A and the CG portion 304B. WL portions 308A, 308B resulting from proper alignment (thereby giving rise to substantially equal channel lengths), ensuring I_{READ} values of adjacent bitcells 305A/305B are also substantially equal (e.g., in reading operations relative to either logic states of the bitcells). In the present context, “substantially equal” may be taken to mean±5%. FIG. 3B is illustrative of a pattern arrangement 300B where WL/EG pattern 303 is misaligned to underlying CG portions 304A, 304B in one direction, resulting in a shorter (or smaller) WL portion 308A for a first bitcell (e.g., bitcell 305A) and a longer (or larger) WL portion 308B for a second bitcell (e.g., bitcell 305B) adjacent to first bitcell 305A. Consequently, higher I_{READ} values of bitcell 305A may be observed compared to the I_{READ} values of bitcell 305B. FIG. 3C is illustrative of a pattern arrangement 300C where WL/EG pattern 303 is misaligned to underlying CG portions 304A, 304B in another direction opposite to the direction of misalignment exemplified in FIG. 3B. Accordingly, a longer/larger WL portion 308A is generated for first bitcell (e.g., bitcell 305A) whereas a shorter/smaller WL portion 308B is generated for second bitcell (e.g., bitcell 305B) adjacent to first bitcell 305A. As a result, lower I_{READ} values of bitcell 305A may be observed compared to the I_{READ} values of bitcell 305B.

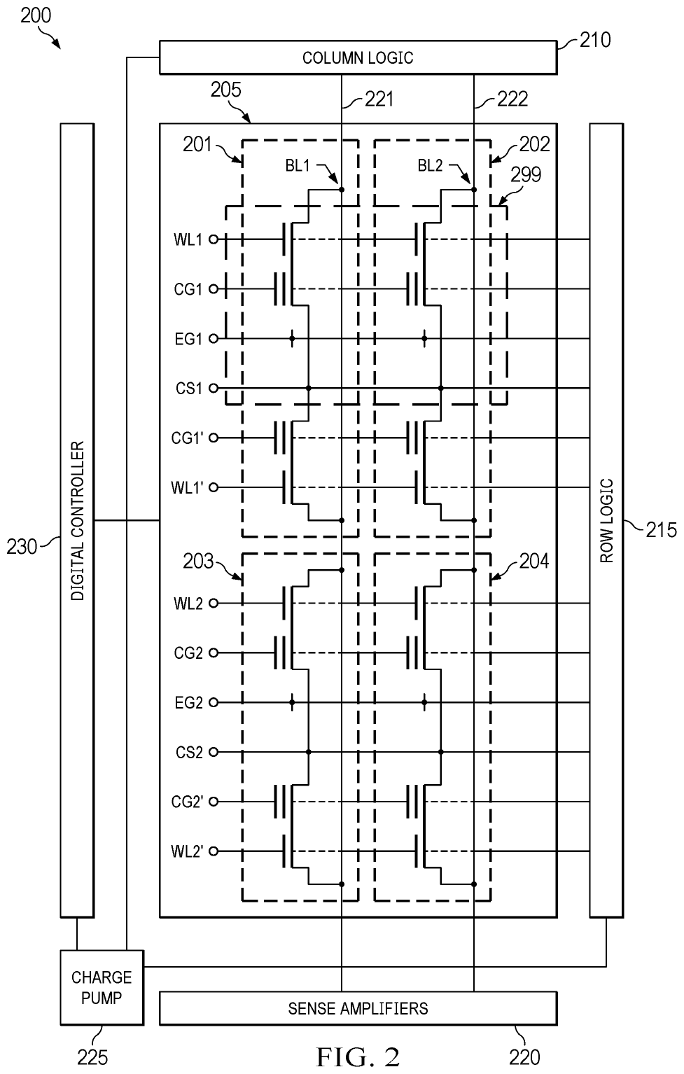

FIG. 2 depicts an IC device having a memory array including a plurality of bitcells, which may comprise bitcells exemplified by bitcells 70/80 of FIG. 1A, wherein I_{READ} characteristics of bitcells may be determined in response to WL asymmetry between adjacent bitcells according to some examples of the present disclosure. Example IC 200 may include a bitcell array 205, row logic circuitry 215, column logic circuitry 210, sense circuitry 220 comprising a plurality of sense amplifiers, a bitcell array controller 230, and charge pump circuitry 225. In some arrangements, example bitcell array 205 may include multiple bitcells coupled in series and/or in parallel. For example, bitcell array 205 may include bitcell groups 201, 203 coupled in series, wherein each bitcell group is coupled to a bitline 221. Bitcell array 205 further exemplifies bitcell groups 202, 204 also coupled in series, wherein each bitcell group is coupled to a bitline 222. In one arrangement, a bitcell portion 299 exemplifies a pair of adjacent bitcells analogous to bitcells 70/80 shown in FIG. 1A, wherein gate pattern misalignment may cause different read currents be generated on respective bitlines BL1 221 and BL2 222 that may be sensed by sense circuitry 220. As will be set forth further below, an I_{READ} characterization and compensation system may be provided according to some examples for determining one or more implant characteristics for the bitcells after gate patterning so as to cause the generation of matched or balanced read currents even where there is a gate pattern misalignment. Herein, “matched” or “balanced” read currents are equal to within ±10%.

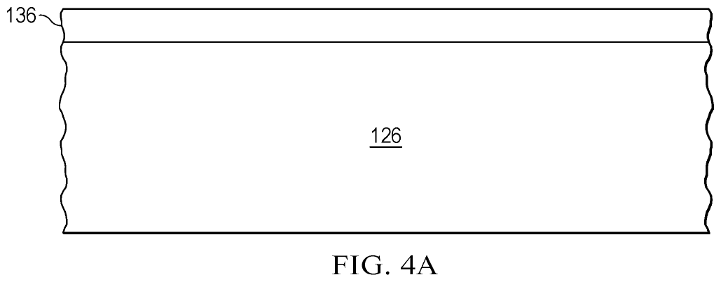

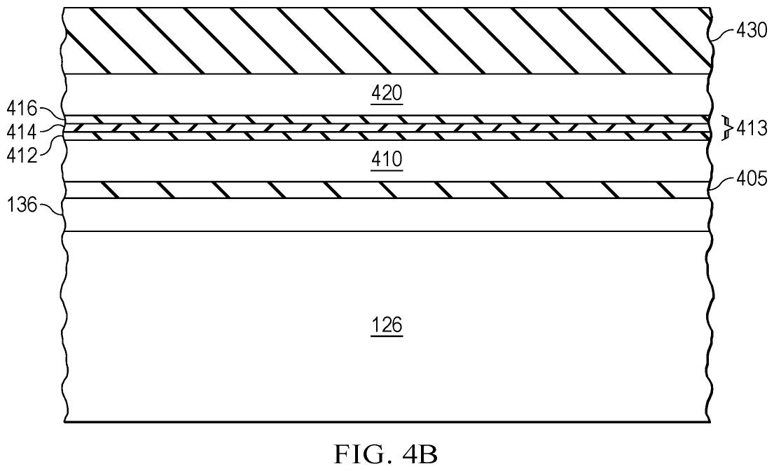

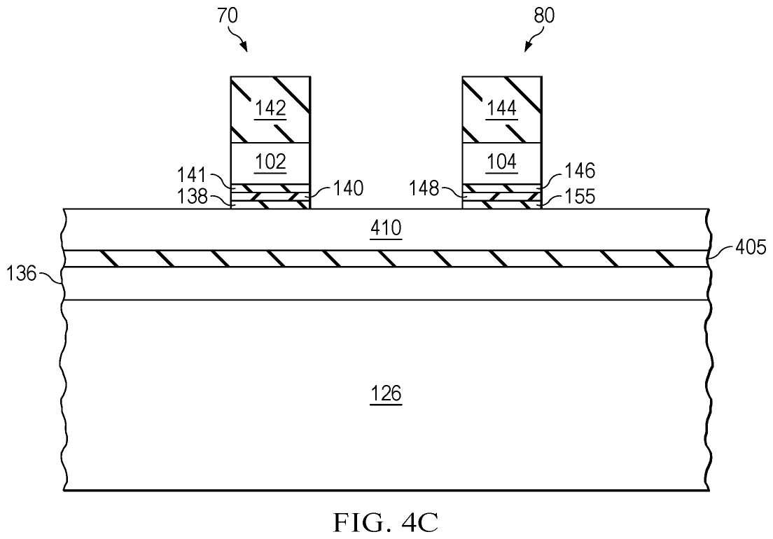

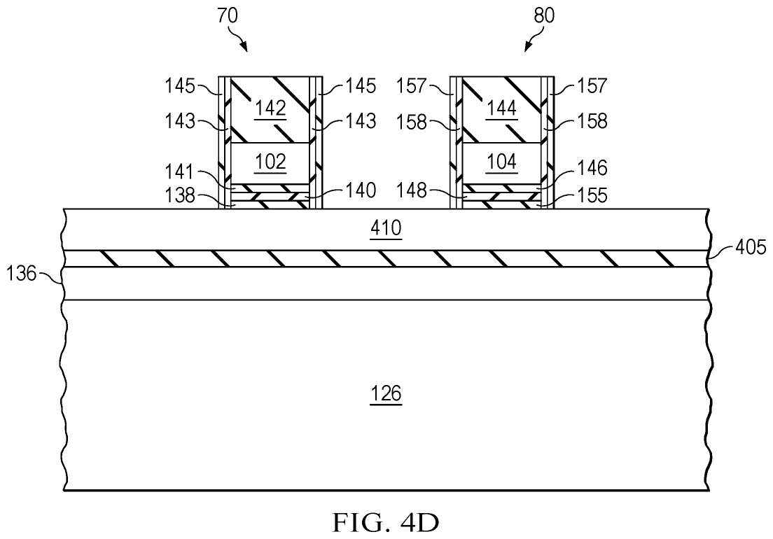

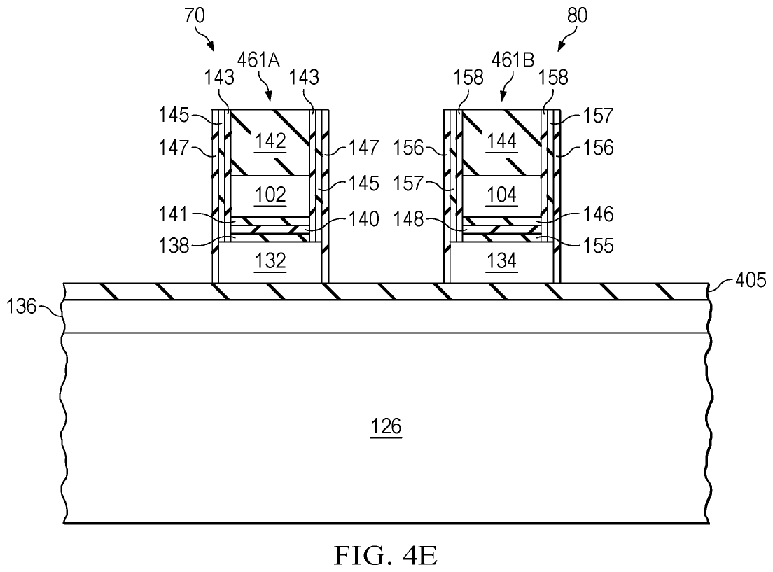

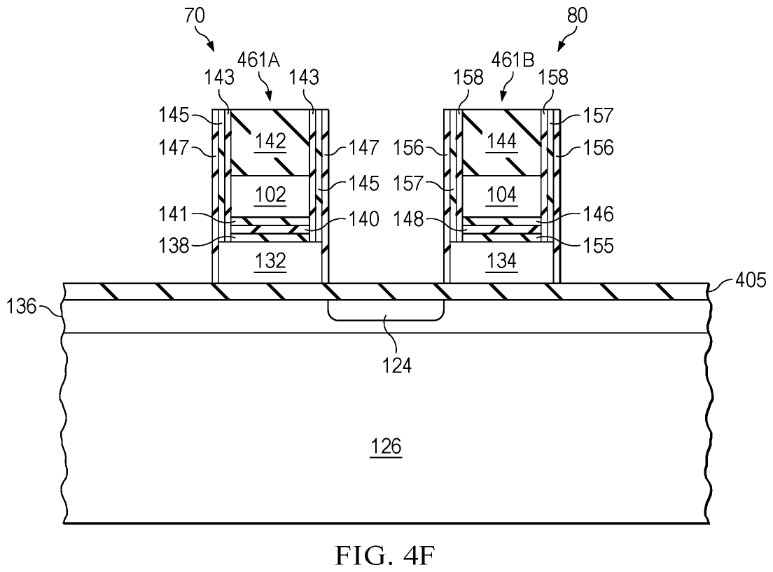

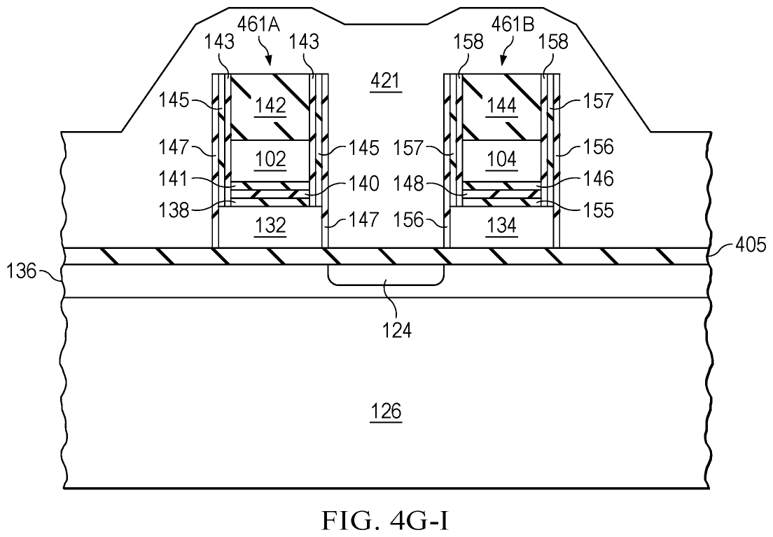

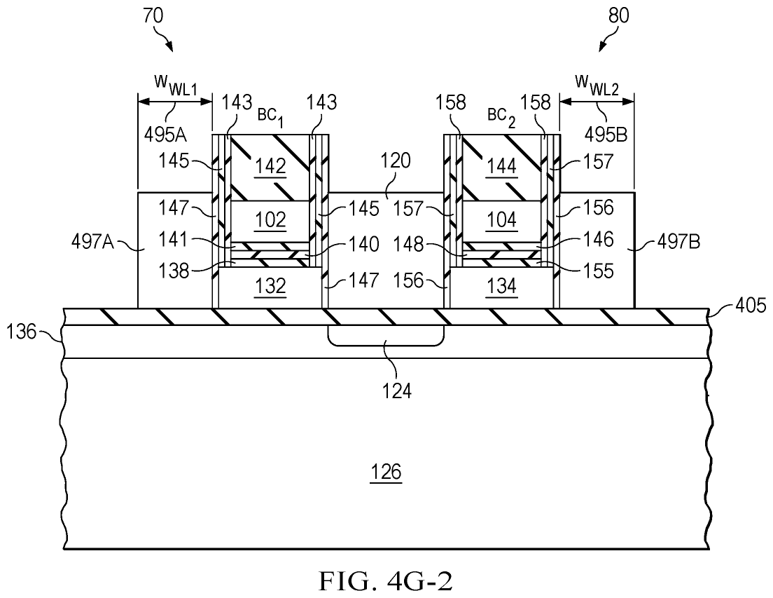

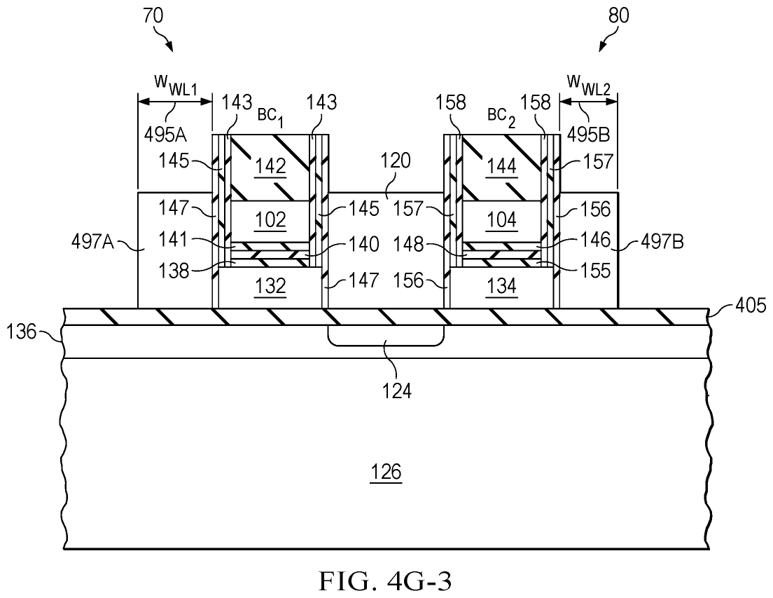

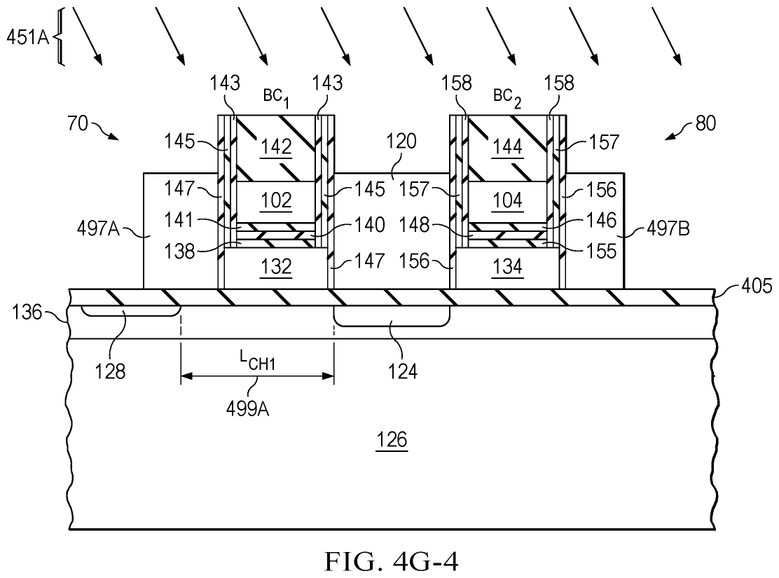

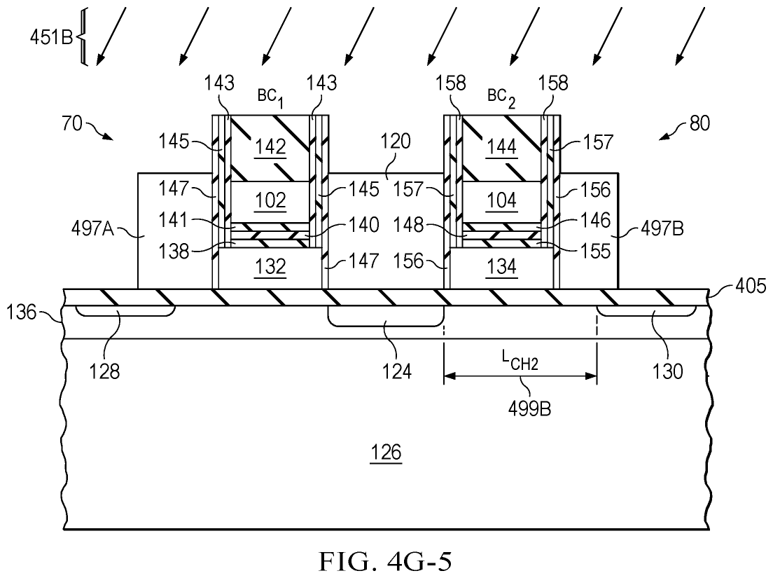

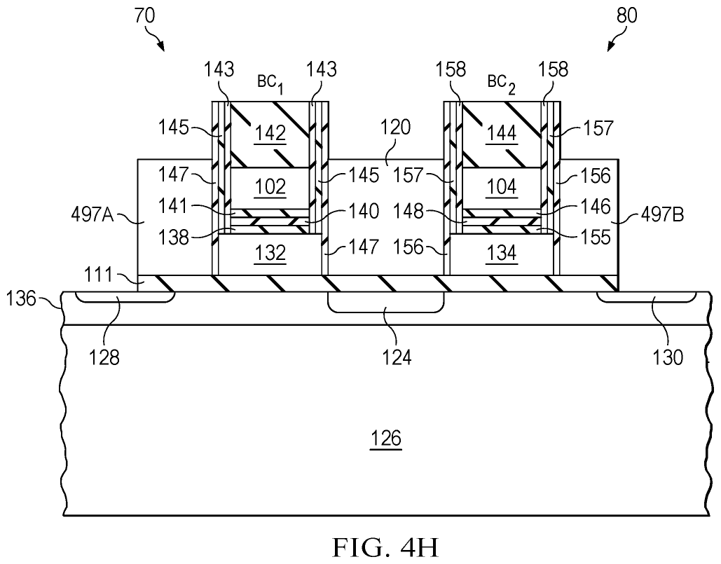

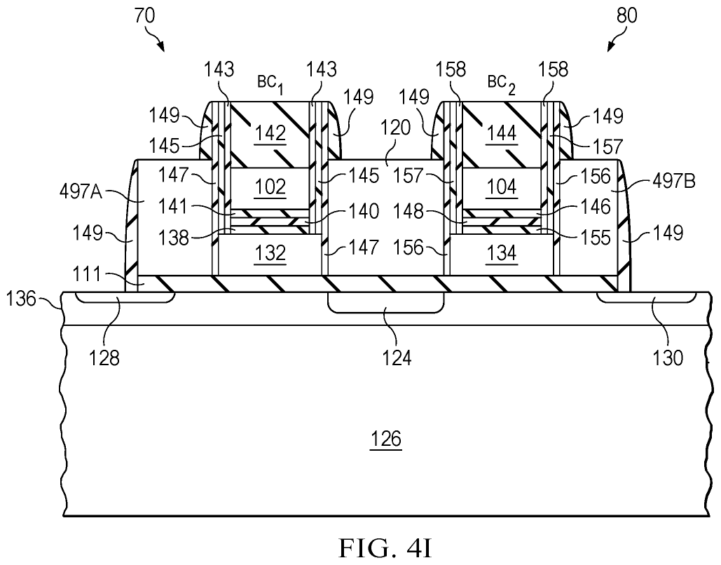

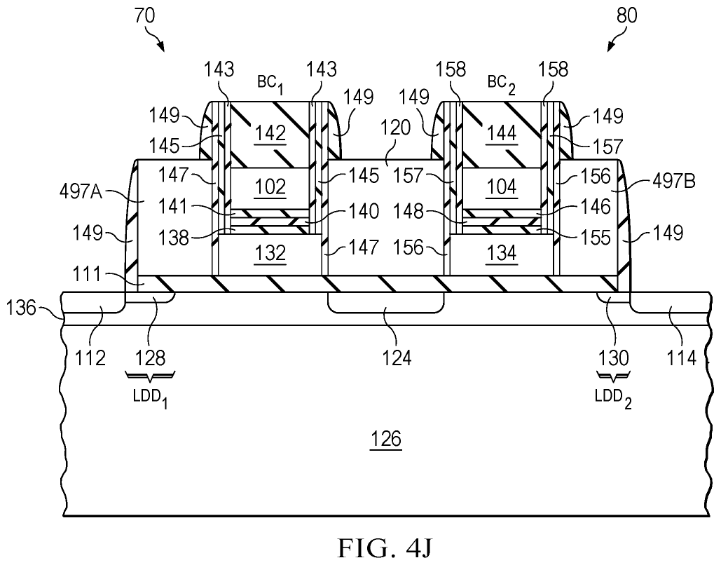

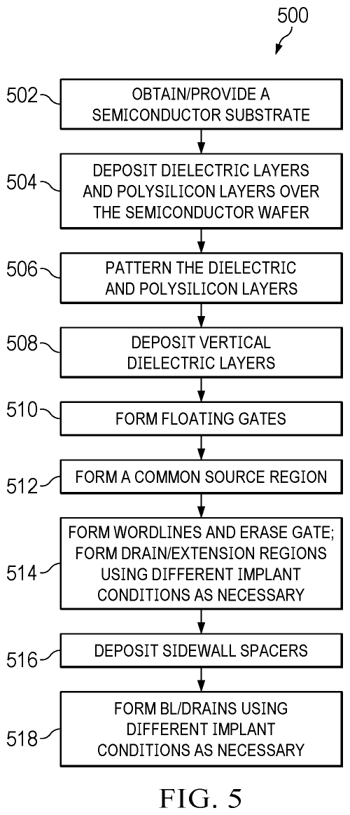

FIGS. 4A-4J depict a plurality of process stages for fabricating a pair of adjacent bitcells, e.g., bitcells 70 and 70 shown in FIG. 1A, wherein implant characteristics may be determined to provide matched I_{READ} of the bitcells according to some examples. FIG. 5 depicts an illustrative example method 500 for fabricating representative bitcells according to some examples. In one implementation, method 500 may be performed to form an IC device including a Flash memory having a plurality of representative bitcells 70/80. In the following passages, method 500 is described in association with FIGS. 4A-4J, which illustrate cross-sectional views of the process stages with respect to forming bitcells 70/80. As set forth below in detail, various fabrication processes may be employed to fabricate bitcells and example fabrication processes, in some implementations, may include deposition, etching, implantation, photolithography, annealing, and other suitable processes.

Method 500 may begin with obtaining or providing a semiconductor process wafer operable as substrate 126 having doped region 136 (block 502; FIG. 4A). Semiconductor substrate 126, in some examples, may predominantly include silicon although other suitable semiconductor materials such as, e.g., Ge, GaAs, SiC, GaN, other Group III-V materials, etc. may be used in some implementations. In some examples, doped region 136 may be formed by doping the substrate 126 with a p-type dopant, e.g., boron, via an implantation process. A plurality of dielectric layers and polysilicon layers may be deposited, grown and/or otherwise formed on or above semiconductor substrate 126 as part of block 504. Some of the example layers are illustrated in FIG. 4B. In some arrangements, block 504 may include forming a dielectric layer 405 comprising silicon dioxide grown on semiconductor substrate 126. Block 504 may further include depositing a polysilicon layer 410 using, e.g., by chemical vapor deposition (CVD), over dielectric layer 405. A portion of polysilicon layer 410 may be subsequently patterned to form floating gate 132 of bitcell 70 and floating gate 134 of bitcell as will be set forth further below. Continuing to refer to FIG. 4B, block 504 may further include depositing a dielectric layer 413 over polysilicon layer 410 using, e.g., a CVD process. Dielectric layer 413 may comprise one or more layers, e.g., as a tri-layer structure, which may include two dielectric layers 412, 416 comprising silicon dioxide that may sandwich a dielectric layer 414 comprising silicon nitride. Block 504 may also include forming another polysilicon layer 420, e.g., by using a CVD process, over dielectric layer 413, as well as forming another dielectric layer 430 over polysilicon layer 420. In some arrangements, dielectric layer 430 may include silicon nitride deposited in a CVD process.

At block 506, patterning operations may be performed with respect to one or more layers formed over semiconductor substrate 126 as set forth above. For example, block 506 may include the following operations as part of forming gate stack structures for bitcells 70 and 80 as exemplified in FIG. 4C: patterning dielectric layer 430 to form the dielectric layers 142, 144 (as exemplified in FIG. 1A); patterning polysilicon layer 420 to form the control gates 102, 104 (as exemplified in FIG. 1A); and patterning dielectric layers 412, 414, 416 to form dielectric layers 138, 140, 141, respectively, relative to bitcell 70, and dielectric layers 155, 148, 146, respectively, relative to bitcell 80 (as exemplified in FIG. 1A). The patterning process of block 506 may, in some examples, be performed using photolithography and dry plasma etching techniques, where appropriate CG masking suitably aligned for facilitating overlay control as described herein may be deployed.

At block 508, dielectric layers 143, 145 and dielectric layers 158, 157 may be formed relative to bitcells 70, 80, respectively, using, e.g., a deposition and etch process, as exemplified in FIG. 4D. Dielectric layers 143, 145 may be deposited such that they are positioned on both sides of the stack formed of dielectric layers 138, 140, 141, 142, as well as a polysilicon layer for the control gate 102 with respect to bitcell 70. Likewise, dielectric layers 158, 157 may be deposited for bitcell 80 such that they are positioned on both sides of the stack formed of dielectric layers 155, 148, 146, 144, as well as a polysilicon layer for the control gate 104. In some examples, dielectric layers 143, 145 may extend from the top of dielectric layer 142 to a top surface of polysilicon layer 410 with respect to bitcell 70. Likewise, the dielectric layers 158 and 157 are also formed with respect to bitcell 80, extending from the top of dielectric layer 142 to the top surface of polysilicon layer 410. In some examples, dielectric layers 143, 158 may comprise silicon dioxide and dielectric layers 145, 157 may include silicon nitride.

At block 510, polysilicon layer 410 may be etched to form floating gates 132, 134 relative to bitcells 70 and 80, respectively, forming corresponding gate stack structures 461A, 461B therefor, as exemplified in FIG. 4E. In an example arrangement, the patterned gate nitride layer defining the dielectric layers 142, 144 may be used as a self-aligned hard mask wherein dry plasma may be implemented for etching. After forming floating gates 132, 134, dielectric layer 147 and dielectric layer 156 may be deposited by using a CVD process with respect to bitcells 70, 80, respectively. In one arrangement, with respect to bitcell 70, dielectric layer 147 may extend from the top of dielectric layer 142 to a top side or surface of dielectric layer 405 formed in block 504. Likewise, dielectric layer 156 may extend from the top of dielectric layer 144 to the top side or surface of dielectric layer 405. In some arrangements, dielectric layers 147, 156 may comprise silicon dioxide. In some arrangements, dielectric layer 147 may be formed to provide horizontal isolation between floating gates 132, 134 and the gates that will be formed in the subsequent operations relative to bitcells 70, 80 (e.g., wordline 118 of bitcell 70 and wordline 122 of bitcell 80 as well as the shared erase gate 120 therebetween, as illustrated in FIG. 1A).

Method 500 may thereafter proceed to block 512 that includes forming common source line 124 by implanting n-type dopants, e.g., arsenic, phosphorus, etc. into semiconductor substrate 126, as exemplified in FIG. 4F. In some arrangements, an ion implantation process having suitably tuned process parameters, e.g., dopant dosage or concentration, implant energy, implant angle, etc., may be deployed. Following the formation of the common source line 124, which may be shared between adjacent bitcells 70 and 80 as noted previously, method 500 may proceed to block 514 that includes forming of the wordline and erase gates for the adjacent bitcells 70, 80, e.g., by patterning a polysilicon layer using a WL/EG composite gate pattern (such as, e.g., gate pattern 165 shown in FIG. 1B) that is desired to be aligned to the underlying control gates 102, 104.

FIGS. 4G-1 to 4G-5 depict cross-sectional views relative to the formation of wordline and erase gates for bitcells 70, 80, wherein an example misalignment between the composite gate pattern with respect to the pattern of control gates 102, 104 leading to asymmetrical bitcell channel lengths is illustrated. In some arrangements, block 514 may include depositing a polysilicon layer 421 as a gate electrode layer (e.g., using a CVD process) over the stack structures 461A, 461B as well as the dielectric layer 405, as exemplified in FIG. 4G-1. In some arrangements, polysilicon layer 421 may be patterned using photolithography and dry plasma etching techniques. Where there is no misalignment of the composite gate pattern to the control gates 102, 104, wordlines 497A, 497B having the same widths 495A, 495B may be formed relative to bitcells 70, 80, respectively, as well as a self-aligned erase gate 120 therebetween, as exemplified in FIG. 4G-2. Skilled artisans will readily recognize that wordlines 497A, 497B are analogous to the wordlines 118, 122 shown in FIG. 1A having equal design widths. FIG. 4G-3 exemplifies a scenario in which there is a misalignment of the WL/EG composite gate pattern to the control gates 102, 104 in one lateral direction, e.g., to the left as illustrated in FIG. 3C, resulting in wordline 497A of bitcell 70 having a greater width than the width of wordline 497B of bitcell 80. Because of the asymmetrical nature of the wordline widths 495A, 495B, bitcells 70, 80 could have asymmetrical channel lengths, as described above with respect to FIGS. 3A-3C, without compensating for the misalignment. To compensate for the asymmetrical channel lengths, thereby achieve balanced I_{READ} performance characteristics between bitcells 70, 80, examples of the present disclosure may be configured to form respective drain regions of bitcells 70, using different implant conditions or parameters. Such different conditions may be determined based on an I_{READ} characterization and compensation scheme as will be set forth in detail further below. By way of example, FIG. 4G-4 depicts an arrangement in which a first drain region (e.g., extension region 128) may be implanted by a process illustrated as implant 451A, and FIG. 4G-5 depicts an arrangement in which a second drain region (e.g., extension region 130) may be implanted by a process illustrated as implant 451B that differs from the implant 451A. The implants 451A, 451B may differ in a manner that results in the extension regions 128, 130 differing in one or more physical characteristics, e.g. dopant species, concentration, extent under the respective wordline 497A, 497B, implant energy and/or extent below the surface of the doped region 136. Thus the implants 451A, 451B may differ by one or more of dopant species, implant energy, implant dose or implant angle. The implants 451A, 451B may be performed in a same implant tool using a first stage rotation for the implant 451A, and a second stage rotation for the implant 451B that differs from the first stage rotation, e.g. by 180°. In other examples the second implant 451B may be performed in a same or different implant tool than the first implant 451A wherein the semiconductor substrate 126 is placed at a first orientation on a process stage with respect to a fixed implant direction for the first implant 451A, and placed at a second orientation on the same or a different process stage with respect to a fixed implant direction for the second implant 451B.

The first implant 451A results in a channel with length L_{CH1} for the bitcell 70 (FIG. 4G-4) and a channel with length L_{CH2} for bitcell 80 (FIG. 4G-5). In some examples the different implants 451A and 451B result in a same channel length for the bitcells 70, 80, e.g., L_{CH1}=L_{CH2}, despite the different of widths of the WLs 497A, 497B. In other examples L_{CH1}≠L_{CH2}, but I_{READ} of the bitcell 70 matches the I_{READ} of the bitcell 80. In such examples the doping of the extension region 128 and the extension region 130 and/or the bitlines 112, 114 may compensate for the difference of channel widths such that the I_{READ} of the bitcell 70 matches the I_{READ} of the bitcell 80. FIG. 4H depicts an arrangement where L_{CH1}≠L_{CH2}, that may be compensated using one or more asymmetrical implant conditions, e.g., resulting in the drain/extension region 128 of the bitcell 70 extending further under WL 497A than the drain/extension region 130 extending under WL 497B.

Method 500 may also include forming dielectric sidewall spacers 149 (block 516) on the vertical sides of wordlines 497A, 497B and dielectric layers 147, 156 as exemplified in FIG. 4I. In some examples, sidewall spacers 149 may be formed by deposition of a silicon nitride layer followed by blanket etch. Method 500 may include block 518 for forming respective bitlines or drains, e.g., bitlines 112, 114, relative to bitcells 70, 80, by implanting n-type dopants, e.g., arsenic, phosphorus, etc. into semiconductor substrate 126, as exemplified by FIG. 4J, which may be implanted using different implant conditions according to some example arrangements herein.

As will be set forth in detail below, doped extension regions 128, 130 as well as bitline/drain 112 and bitline/drain 114, may be formed based on asymmetrical implant conditions relative to bitcells 70, 80 depending on appropriate gate overlay control measurements obtained from suitable inline metrology tooling implemented in association with the WL/EG formation set forth above. In an example arrangement, an I_{READ} characterization and compensation system may be configured to provide appropriate control signals for selecting one or more implant variables with respect to the ion implantation processes used in forming bitline/drain 112 and bitline/drain 114 and/or any extension regions 128, 130 that may be formed prior to forming the bitlines/drains of bitcells 70, 80.

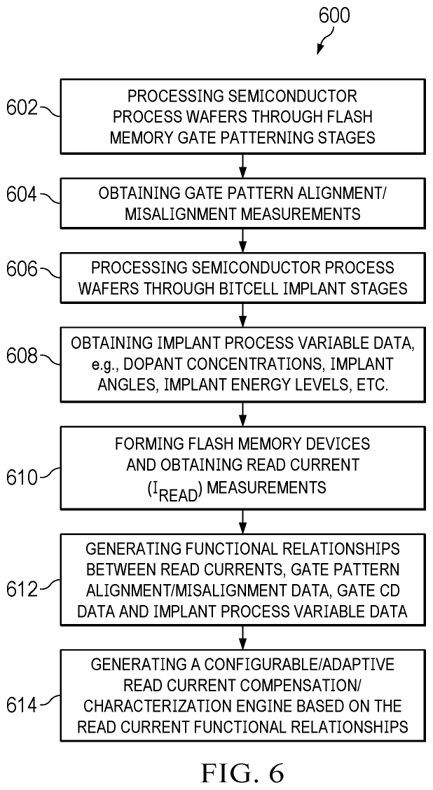

FIG. 6 is a flowchart associated with an I_{READ} characterization and compensation scheme based on read current modeling of Flash memory devices according to some examples of the present disclosure. At block 602, example method 600 may commence with processing a plurality of semiconductor process wafers containing Flash memory devices through various stages according to a fabrication flow including a plurality of gate patterning stages as set forth above. In some implementations, the semiconductor process wafers may comprise one or several wafer lots, each lot comprising a set of wafers, e.g., 25 wafers, wherein any varying number of lots and/or wafers may be utilized in read current modeling according to some examples herein. In some implementations, the semiconductor process wafers may comprise test wafers, product wafers, and/or any combination thereof. In some implementations, the semiconductor process wafers may be run through a specific fabrication flow wherein the various stages are performed using a particular sequence of tooling/equipment. At block 604, various gate pattern alignment/misalignment measurements (e.g., WL/EG overlay alignment to CG/FG patterning) may be obtained or measured by appropriate metrology equipment. At block 606, the semiconductor process wafers may be processed through one or more bitcell implant stages, e.g., with respect to bitline/drain implants, LDD implants and/or other implants such as halo or pocket implants, depending on the implementation and/or fabrication flow. At block 608, data relating to a plurality of implant process variables or parameters used in performing the implant stages may be obtained, e.g., dopant dosages/concentrations, implant angles, implant energy levels, and the like. The semiconductor process wafers may be processed through various subsequent process stages of the fabrication flow to form Flash memory devices that can be electrically tested. As exemplified at block 610, electrical measurements may include obtaining read current (I_{READ}) measurements, e.g., with respect to reading the data in erased and programmed states of the Flash memory bitcells. Depending on implementation, I_{READ} data may be obtained and/or combined at different levels of granularity, e.g., at a per die level, which may be measured across the entire wafer or at specific locations of the wafer.

At block 612, a plurality of empirical relationships between I_{READ} data, gate pattern alignment/misalignment data, gate critical dimension (CD) data and implant process variable data may be obtained. In some examples, various mathematical and statistical techniques such as, e.g., multivariate regression analysis, analysis of variance, etc. may be employed in obtaining such functional relationships. In general, example functional relationships may be determined based on correlating between the measured read currents and the gate pattern (mis)alignment measurements (Δx) as well as correlating between the measured read currents and a set of the implant process variables {Var1, Var2, Var3, . . . } as exemplified below where F and G represent suitable mathematical functions:

I_{READ}(Measured)=F(Δx)

I_{READ}(Measured)=H(Var1,Var2,Var3, . . . )

In one implementation, based on the relationships between the gate pattern (mis)alignment data and the implant process variable data via the measured read currents, an adaptive read current compensation/characterization (RCCC) engine may be configured (e.g., as a polynomial interpolation/extrapolation engine) that may be deployed as a computer-executable entity operable in response to program instructions and input data (block 614). In some examples, the RCCC engine may be deployed for determining appropriate values with respect to one or more implant process variables for a given gate pattern misalignment measured by inline metrology tools in a process flow substantially similar to the process flow that has been implemented in fabricating the semiconductor process wafers used read current modeling as set forth above. Skilled artisans will recognize upon reference hereto that an implementation of the foregoing scheme may be deployed as a pre-production I_{READ} characterization system as well as an I_{READ} compensation system operable in a production flow where gate pattern (mis)alignment data may be provided as an input to modulate the implant process variables and parametrics in order to proactively compensate for potential I_{READ} mismatching due to any inline gate pattern (mis)alignment. In still further arrangements, an implementation of the foregoing scheme may be deployed as a dynamically adaptive RCCC engine configured to provide feedback and/or feedforward control signals based on the I_{READ} measurements and gate pattern (mis)alignment data obtained from product wafers, wherein the feedback control signals may be provided to appropriate fab equipment, e.g., implanters, photolithography equipment, etc., to vary the process parameters so that the I_{READ} characteristics of subsequent product wafers may be modulated or “tuned” as needed.

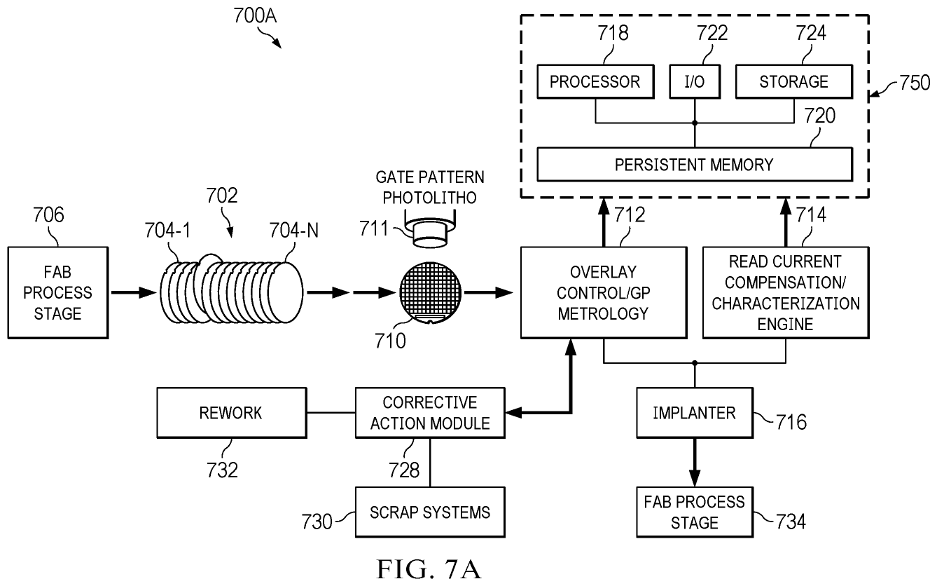

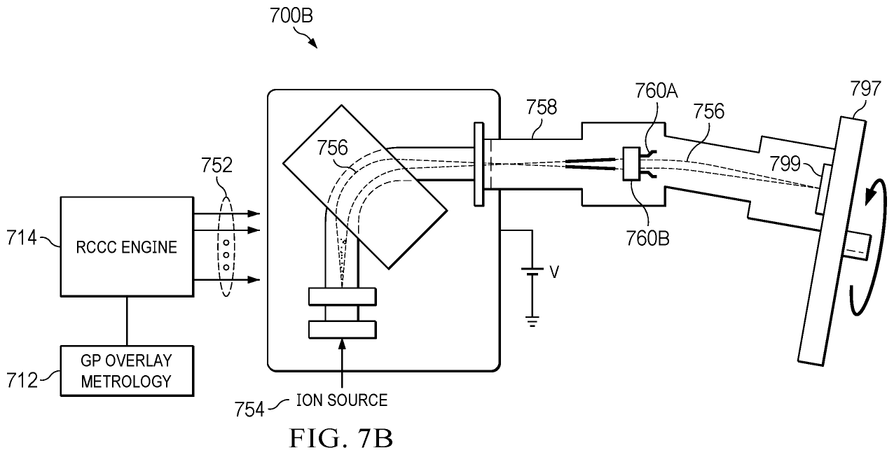

FIG. 7A depicts a system for facilitating I_{READ} compensation in association with gate pattern overlay control during the fabrication of an IC according to some examples of the present disclosure. By way of illustration, example system 700A may be configured to execute an implementation of the RCCC scheme set forth in FIG. 6, wherein a generalized process stage 706 is exemplified that may represent one or more gate patterning stages in the fabrication of a Flash memory device. A plurality of wafers 704-1 to 704-N may be processed, e.g., as a wafer lot 708, in a gate pattern photolithography step using appropriate photolithography equipment 711 operative with overlay control metrology tooling 712, such as inline overlay control and gate pattern (GP) metrology equipment. Overlay control metrology tooling 712 may be configured to detect, measure or otherwise obtain, gate (mis)alignment data with respect to WL/EG and CG/FG patterning at predetermined locations on a process wafer, e.g., wafer 710. RCCC engine 714 may be configured to receive gate (mis)alignment data from overlay control metrology tooling 712. In response, RCCC engine 714 is operable to determine appropriate adjustments to one or more implant process variables associated with an implanter 716. As previously noted, example implant process variables that may be varied from a default or initial value may comprise, without limitation, BL/drain dopant concentrations, LDD and/or or halo implant concentrations, implant energy levels, implant angles and/or wafer holder tilt angles, speeds at which a wafer may be traversed across an ion beam, etc., any of which may be selectively varied depending on the gate alignment data in conjunction with the particular gate patterning stages preceding the implant operation. Processed wafer lot 702 may proceed to a next process stage 734 after going through the selectively/optionally modulated implant process according to an example implementation.

As previously noted, WL/EG and CG/FG gate misalignment capable of affecting read currents may occur even where the overlay control rules are satisfied. Where the process wafers do not satisfy applicable WL/EG and CG/FG gate alignment overlay thresholds, such process wafers may be staged for corrective actions executed by a module 728 that may determine scrap or rework options as indicated by blocks 730 and 732.

Depending on implementation, overlay control metrology tooling 712 and/or RCCC engine 714 may be configured as separate components or integrated as an inline process control system, wherein a computing platform 750, e.g., a workstation or a server, having one or more processors 718 coupled to a persistent memory 720 containing machine-executable code or program instructions, may be configured to effectuate appropriate GP metrological operations and/or implant process modulation control signals for I_{READ} compensation. Example computing platform 750 may also include one or more storage modules 724 and one or more input/output (I/O) modules 722 for facilitating storage of the GP data and I_{READ} data at various levels of granularity, e.g., die level, wafer region level, wafer lot level, etc. that may be used for read current modeling. In some arrangements, wafer level I_{READ} maps may be developed based on the historical data, where different regions may exhibit certain predictable types of I_{READ} variations across the wafer(s) due to, e.g., characteristic exposure signatures of the photolithography equipment being used. Such regional variations in I_{READ} (which may be captured as absolute measurement values, ratios, percentages, etc.) may also be used as an input for modifying the implant process variables in an example implementation.

Because of the symmetrical nature of BL/drain formation in adjacent bitcell pairs an example Flash memory cell architecture, an example implementation may involve a single implanter for implanting both sets of bitcells by orienting the process wafers in two separate orientations, wherein the implant beams may be directed to the process wafer from opposing directions. In additional and/or alternative arrangements, two separate implanters may be used (e.g., substantially matched in performance characteristics), wherein one implanter may be deployed for implanting one set of bitcells in an array from one side and another implanter may be deployed for implanting the mirror set of bitcells in the array from the opposite side. Regardless of whether a single implanter configuration or a double implanter configuration is deployed, an example implementation of RCCC engine 714 may be configured to modulate one or more implant process variables of respective implanter(s) in order to compensate for any I_{READ} mismatching due to the GP misalignment.

FIG. 7B depicts a generalized implanter modulation subsystem 700B including and/or operable in association with RCCC engine 714 for tuning bitcell read characteristics according to some examples of the present disclosure. As described above, RCCC engine 714 is operable responsive to GP metrology data from overlay control and metrology tooling 712. Example implanter 716 may include an ion source 754 for providing suitable dopant species in an ion beam 756 that may be accelerated via an acceleration tube 758 at predetermined energy levels. X-scan plates 760A and Y-scan plates 760B may be provided for directing the ion beam 756 to a target process wafer 799 which may be placed in a rotating holder 797. One or more control signals 752 may be generated by RCCC engine 714 based on the GP (mis)alignment data for modulating the dopant concentrations generated by ion source 754, implant angles effectuated by X- and/or Y-scan plates 758A/B and acceleration energy levels effectuated by acceleration tube 758 for achieving a suitable profile in the BL/drain region.

Due to the symmetrical nature of WL/EG and CG/FG patterning in forming the BL/drain implant regions in adjacent bitcell pairs an example Flash memory cell architecture, if the misalignment causes one bitcell's WL to be extended along the channel axis, the read currents of that bitcell may be decreased whereas the read currents of the adjacent bitcell may be increased (because of the shortened WL) as noted above in reference to the gate alignment patterns shown in FIGS. 3A-3C. On the other hand, if there is a gate pattern misalignment along a coplanar axis perpendicular to the channel length, such misalignment may not cause a mismatched I_{READ} condition because the lengths of respective WLs of the adjacent bitcells essentially remain the same although the WLs may be off-centered with respect to the underlying CG/FG geometry.

In general, mismatched read currents associated with sensing of the erased states rather than the programmed states of Flash memory bitcells are more susceptible to causing potential false data reads because the read current variations in sensing the programmed bitcells may not be sufficient to disturb the sense trip currents configured for a memory design. Because it is generally the lowering of read currents in the erased state of the bitcells that can give rise to false data, an RCCC engine may be configured in some arrangements to generate implant modulation control signals only with respect to the implanting of BL/drains of the bitcells having WLs with a width greater than a design width. It may be desirable, however, that the read current characteristics of both bitcells in an adjacent bitcell pair (e.g., bitcells 70 and 80 shown in FIG. 1A) be matched as closely as possible. Accordingly, the BL/drain implants of both bitcells (one having an extended WL and the other having a shortened WL) may be adjusted by an RCCC engine in some example implementations. Depending on how the doped profiles of a drain region are configured in a particular memory cell design, any combination of drain implants, LDD implants, and/or halo or pocket implants may be adjusted independently or otherwise in response to one or more implant process modulation control signals generated by a suitably calibrated RCCC engine in order to achieve the desired matching read currents. For example, a bitcell having an extended WL may receive a lower halo/pocket dose of dopant species whereas a bitcell having a shortened WL may receive a higher halo/pocket dose in some arrangements.

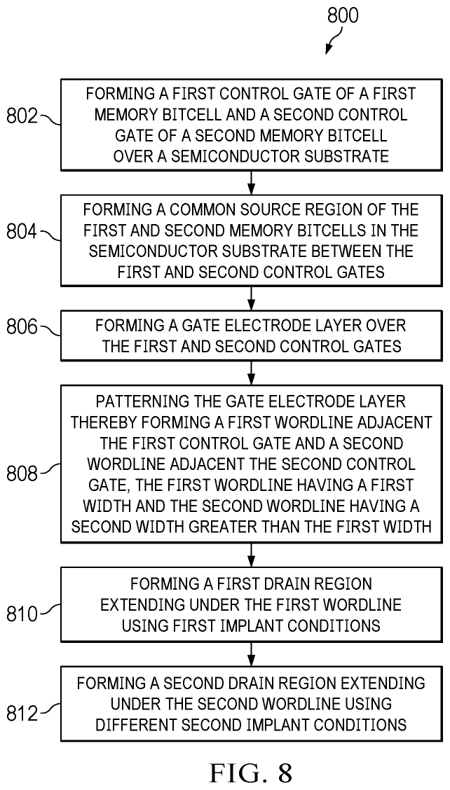

FIG. 8 is a flowchart of an IC fabrication method 800 according to some examples of the present disclosure. At block 802, a first control gate of a first memory bitcell and a second control gate of a second memory bitcell are formed over a semiconductor substrate. At block 804, a common source region of the first and second memory bitcells is formed in the semiconductor substrate between the first and second control gates. At block 806, a gate electrode layer is formed over the first and second control gates. At block 808, the gate electrode layer is patterned, thereby forming a first wordline adjacent the first control gate and a second wordline adjacent the second control gate, the first wordline having a first width and the second wordline having a second width, which may be greater than the first width. Thereafter, a first drain region extending under the first wordline using first implant conditions or parameters and a second drain region extending under the second wordline using different second implant conditions or parameters are formed with respect to the first and second memory bitcells, as set forth at blocks 810, 812.

In some arrangements, a misalignment between the wordline/erase gate pattern and the control gates of the bitcells may be determined as set forth above. In some arrangements, one or more implant conditions for implanting a dopant in a drain and/or extension region of the semiconductor substrate may be selected responsive to the misalignment. In some arrangements, the determining may include determining that the misalignment between the wordline and the control gate causes a lengthening or shortening of the wordline (e.g., by a certain amount) along a direction parallel to a channel length of the memory bitcell. In some arrangements, the selection of implant conditions may comprise adding or subtracting from a value predetermined for WLs of equal width, e.g., adjusting at least one of a dosage of the dopant to be implanted in the drain and/or extension region, an implant angle for targeting an ion beam containing the dopant towards the semiconductor substrate, and/or an implant energy level associated with the ion beam, wherein the adjusting may be performed responsive to determining a suitable read current compensation with respect to reading an erase state of the memory bitcell. In some arrangements, the read current compensation may be performed or determined based on a read current characterization engine operable with an implanter configured to implant the dopant in the substrate. As previously set forth, the read current characterization engine may be configured to operate responsive to inline measurements relating to the wordline and the control gate alignment or misalignment. In some arrangements, the dosage of a dopant species may be increased or decreased based on an amount of the lengthening or shortening of the wordline of the memory bitcell, e.g., relative to the wordline of an adjacent memory bitcell and/or some baseline measurements. In similar fashion, further example implementations may involve increasing or decreasing the implant energy levels and/or the implant angles based on an amount of the lengthening or shortening of the wordline of the memory bitcell. In still further implementations, an example method may comprise determining that a misalignment between the wordline and the control gate of a bitcell is within a gate processing overlay control window. An overlay control window may be defined, e.g., by a maximum allowable misalignment between the wordline and the control gate in one or more directions lateral with respect to the substrate surface.

In some baseline configurations, an example implementation may have the following implant parameters: halo implant of boron at around 6.4×10¹³ atoms/cm², with an implant energy level of around 10 keV, with a 30° tilt and 0° twist for two rotations; and an LDD implant of arsenic at around 1.0×10¹⁴ atoms/cm², with an implant energy level of around 15 keV. In some examples, I_{READ} values for erase read operations may range from around 20 μA to around 55 μA. In some examples, WL gate to control gate overlay threshold windows may comprise 20 nanometers (nm) along a first horizontal axis and ≤17 nm along a second horizontal axis perpendicular to the first horizontal axis. Accordingly, whereas process wafers showing WL gate to control gate overlay measurements greater than the foregoing windows may be dispositioned for scrap/rework, process wafers showing WL gate to control gate overlay measurements within the applicable windows may still exhibit a misalignment thereby requiring compensatory implant process modulation for providing balanced I_{READ} characteristics according to some examples herein.

Although example implementations have been set forth above with respect to NMOS-based split-gate Flash memory bitcells, skilled artisans will recognize upon reference hereto that the teachings herein are not limited thereto. Some example implementations may include PMOS-based Flash memory bitcells and/or non-split gate bitcell configurations in additional and/or alternative arrangements. Whereas various drain, LDD and halo/pocket implants have been set forth in some examples, it should be appreciated that a variety of bitline/drain implant profiles may be implemented wherein LDDs and/or halo/pocket implants are not necessary or may be optionally provided. Further, example implementations may involve various Flash architectures, e.g., single-level cell (SLC) Flash architectures (storing one bit of data per cell), multi-level cell (MLC) Flash architectures (storing more than one bit per cell), NAND-based Flash architectures, NOR-based Flash architectures, charge trap Flash architectures etc., as well as other types of nonvolatile memory architectures.

One or more examples of the present disclosure may be implemented using different combinations of software, firmware, and/or hardware. Thus, one or more of the techniques shown in the Figures (e.g., flowcharts) may be implemented using code and data stored and executed on one or more electronic devices or nodes (e.g., a workstation, a network element, etc.). Such electronic devices may store and communicate (internally and/or with other electronic devices over a network) code and data using computer-readable media, such as non-transitory computer-readable storage media (e.g., magnetic disks, optical disks, random access memory, read-only memory, flash memory devices, phase-change memory, etc.), transitory computer-readable transmission media (e.g., electrical, optical, acoustical or other form of propagated signals—such as carrier waves, infrared signals, digital signals), etc. In addition, some network elements or workstations, e.g., configured as servers, may typically include a set of one or more processors coupled to one or more other components, such as one or more storage devices (e.g., non-transitory or persistent machine-readable storage media) as well as storage database(s), user input/output devices (e.g., a keyboard, a touch screen, a pointing device, one or more imaging capturing devices and/or a display, etc.), and network connections for effectuating signaling and/or data transmission. The coupling of the set of processors and other components may be typically through one or more buses and bridges (also termed as bus controllers), arranged in any known (e.g., symmetric/shared multiprocessing) or heretofore unknown architectures. Thus, the storage device or component of a given electronic device or network element may be configured to store program code and/or data for execution on one or more processors of that element, node or electronic device for purposes of implementing one or more techniques of the present disclosure.

At least some examples are described herein with reference to one or more circuit diagrams/schematics, block diagrams and/or flowchart illustrations. It is understood that such diagrams and/or flowchart illustrations, and combinations of blocks in the block diagrams and/or flowchart illustrations, can be implemented by any appropriate circuitry configured to achieve the desired functionalities. Accordingly, some examples of the present disclosure may be embodied in hardware and/or in software (including firmware, resident software, micro-code, etc.) operating in conjunction with suitable processing units or microcontrollers, which may collectively be referred to as “circuitry,” “a module” or variants thereof. An example processing unit or a module may include, by way of illustration, a general purpose processor, a special purpose processor, a conventional processor, a digital signal processor (DSP), an image processing engine or unit, a plurality of microprocessors, one or more microprocessors in association with a DSP core, a controller, a microcontroller, Application Specific Integrated Circuits (ASICs), Field Programmable Gate Array (FPGA) circuits, any other type of integrated circuit (IC), and/or a state machine, as well as programmable system devices (PSDs) employing system-on-chip (SoC) architectures that combine memory functions with programmable logic on a chip that is designed to work with a standard microcontroller. Example memory modules or storage circuitry may include volatile and/or non-volatile memories such as, e.g., random access memory (RAM), electrically erasable/programmable read-only memories (EEPROMs) or UV-EPROMS, one-time programmable (OTP) memories, Flash memories, static RAM (SRAM), etc.

Further, in at least some additional or alternative implementations, the functions/acts described in the blocks may occur out of the order shown in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated. Also, some blocks in the flowcharts may be optionally omitted. Furthermore, although some of the diagrams include arrows on communication paths to show a primary direction of communication, it is to be understood that communication may occur in the opposite direction relative to the depicted arrows. Finally, other blocks may be added/inserted between the blocks that are illustrated.

It should therefore be clearly understood that the order or sequence of the acts, steps, functions, components or blocks illustrated in any of the flowcharts and/or block diagrams depicted in the drawing Figures of the present disclosure may be modified, altered, replaced, customized or otherwise rearranged within a particular flowchart or block diagram, including deletion or omission of a particular act, step, function, component or block. Moreover, the acts, steps, functions, components or blocks illustrated in a particular flowchart may be inter-mixed or otherwise inter-arranged or rearranged with the acts, steps, functions, components or blocks illustrated in another flowchart in order to effectuate additional variations, modifications and configurations with respect to one or more processes for purposes of practicing the teachings of the present disclosure.

At least some portions of the foregoing description may include certain directional terminology, such as, e.g., “upper”, “lower”, “top”, “bottom”, “left-hand”, “right-hand”, “front side”, “backside”, “vertical”, “horizontal”, etc., which may be used with reference to the orientation of some of the Figures or illustrative elements thereof being described. Because components of some examples can be positioned in a number of different orientations, the directional terminology is used for purposes of illustration and is in no way limiting. Likewise, references to features referred to as “first”, “second”, etc., are not indicative of any specific order, importance, and the like, and such references may be interchanged mutatis mutandis, depending on the context, implementation, etc. Further, the features of examples described herein may be combined with each other unless specifically noted otherwise.

Although various implementations have been shown and described in detail, the claims are not limited to any particular implementation or example. None of the above Detailed Description should be read as implying that any particular component, element, step, act, or function is essential such that it must be included in the scope of the claims. Where the phrases such as “at least one of A and B” or phrases of similar import are recited or described, such a phrase should be understood to mean “only A, only B, or both A and B.” Reference to an element in the singular is not intended to mean “one and only one” unless explicitly so stated, but rather “one or more.” All structural and functional equivalents to the elements of the above-described implementations that are known to those of ordinary skill in the art are expressly incorporated herein by reference and are intended to be encompassed by the claims appended below.

What is claimed is:

1. A method of fabricating an integrated circuit (IC), comprising:
forming a first control gate of a first memory bitcell and a second control gate of a second memory bitcell over a semiconductor substrate;
forming a common source region of the first and second memory bitcells in the semiconductor substrate between the first and second control gates;
forming a gate electrode layer over the first and second control gates;
patterning the gate electrode layer thereby forming a first wordline adjacent the first control gate and a second wordline adjacent the second control gate, the first wordline having a first width and the second wordline having a second width;
forming a first drain region extending under the first wordline using first implant parameters; and
forming a second drain region extending under the second wordline using different second implant parameters.

2. The method as recited in claim 1, wherein the first implant parameters include a first dopant species dose and the second implant parameters include a different second dopant species dose.

3. The method as recited in claim 1, wherein the first implant parameters include a first implant angle of a dopant species and the second implant parameters include a different second implant angle of the dopant species.

4. The method as recited in claim 1, wherein the first implant parameters include a first implant energy of a dopant species and the second implant parameters include a different second implant energy of the dopant species.

5. The method as recited in claim 1, wherein the first width is different than the second width, and a first read current of the first memory bitcell is about equal to a second read current of the second memory bitcell.

6. The method as recited in claim 1, wherein the first width of the first wordline is greater than the second width of the second wordline.

7. The method as recited in claim 1, wherein a first channel length of the first memory bitcell is equal to a second channel length of a second memory bitcell.

8. An integrated circuit (IC), comprising:
a first memory bitcell over a semiconductor substrate and including a first gate stack including a first floating gate and a first control gate with a dielectric material disposed therebetween, the first memory bitcell further including a first wordline formed adjacent a drain region of the first memory bitcell, the drain region of the first memory bitcell coupled to a first bitline;
a second memory bitcell spaced apart over the semiconductor substrate from the first memory bitcell by a common source region shared between the first and second memory bitcells, the second memory bitcell including a second gate stack including a second floating gate and a second control gate with a dielectric material disposed therebetween, the second memory bitcell further including a second wordline formed adjacent to a drain region of the second memory bitcell, the drain region of the second memory bitcell coupled to a second bitline; and
an erase gate formed over the common source region,
wherein the drain region of the first memory bitcell has a different dopant profile than does the drain region of the second memory bitcell.

9. The IC as recited in claim 8, wherein a first width of the first wordline is different from a second width of the second wordline.

10. The IC as recited in claim 8, wherein the drain region of the first memory bitcell has a first dopant dosage and the drain region of the second memory bitcell has a different second dopant dosage.

11. The IC as recited in claim 8, wherein the drain region of the first memory bitcell extends further under the first wordline than the drain region of the second memory bitcell extends under the second wordline.

12. The IC as recited in claim 8, wherein the drain region of the first memory bitcell extends deeper into the semiconductor substrate that does the drain region of the second memory bitcell.

13. A Flash memory bitcell, comprising:
a gate stack formed over a semiconductor substrate, the gate stack including a floating gate and a control gate with a dielectric material disposed therebetween;
a common source region formed in the semiconductor substrate adjacent the gate stack;
a first wordline formed adjacent the gate stack;
an erase gate overlapping at least a portion of the common source region; and
a first drain region formed in the semiconductor substrate and extending under the first wordline, and a second drain region formed in the semiconductor substrate and extending under a second wordline, wherein the first wordline has a first width that is different from a second width of the second wordline of an adjacent Flash memory bitcell sharing the common source region with the Flash memory bitcell, and wherein the first drain region has a different physical characteristic with respect to the second drain region.

14. The Flash memory bitcell as recited in claim 13, wherein the first drain region of the first memory bitcell has a first dopant dosage and the second drain region of the second memory bitcell has a different second dopant dosage.

15. The Flash memory bitcell as recited in claim 13, wherein the first drain region of the first memory bitcell extends further under the first wordline than the second drain region of the second memory bitcell extends under the second wordline.

16. The Flash memory bitcell as recited in claim 13, wherein the first drain region of the first memory bitcell extends deeper into the semiconductor substrate that does the second drain region of the second memory bitcell.
